(19) United States
(12) Patent Application Publication
(10) Pub. No.: US 2024/0419067 A1
(43) Pub. Date: Dec. 19, 2024

(54) METHOD FOR MANUFACTURING A MULTISPECTRAL FILTER FOR ELECTROMAGNETIC RADIATION

(71) Applicant: COMMISSARIAT A L'ENERGIE ATOMIQUE ET AUX ENERGIES ALTERNATIVES, PARIS (FR)

(72) Inventor: Ujwol PALANCHOKE, GRENOBLE CEDEX (FR)

(21) Appl. No.: 18/742,381

(22) Filed: Jun. 13, 2024

(30) Foreign Application Priority Data
Jun. 13, 2023 (FR) 2305964

(51) Int. Cl. G03F 7/00; G02B 5/28

(52) U.S. Cl. CPC G03F 7/0007; G02B 5/284

(57) ABSTRACT

A method for manufacturing a multispectral filter for electromagnetic radiation including at least two filters, each filter including a first reflective layer, a second reflective layer, a Fabry-Perot cavity dielectric layer, the method including depositing a layer of structuring material onto a carrier substrate including at least two photoelectric transducers; 3D structuring the layer of structuring material to obtain at least two patterns of different heights, one of the patterns having a maximum reference height relative to the carrier substrate; conformally depositing a first reflective layer; depositing a layer of the dielectric material intended to form the dielectric patterns of the Fabry-Perot cavities; planarising the dielectric material by removal with a selective stop at the top of the highest structuring material pattern, depositing a layer made of the same dielectric material so as to complete formation of the Fabry-Perot cavities and a second reflective layer onto the two Fabry-Perot cavities.

### CROSS-REFERENCE TO RELATED APPLICATIONS

This application claims priority to French Patent Application No. 2305964, filed Jun. 13, 2023, the entire content of which is incorporated herein by reference in its entirety.

### FIELD

The technical field of the invention is that of spectral filtering, especially for imaging applications and making coloured filters for CMOS-type image sensors, liquid crystal display devices or light-emitting diodes. The invention can also be implemented in light-emitting devices.

The present invention relates to a method for manufacturing a multispectral filter for electromagnetic radiation.

### BACKGROUND

A spectral filter or colour filter is used to filter light by wavelength, so as to provide information about the intensity of light in some wavelengths. Several colour filters can be associated so as to form, for example, red-green-blue (RGB) filters that give information about the intensity of these three colours.

Metal/dielectric colour filters made from a Fabry-Perot cavity are especially known. These filters comprise one or more dielectric (or possibly semiconducting) cavities formed between two thin metal films having a metal mirror function so as to form a Fabry-Perot cavity. Generally, the metal/dielectric stacks are different depending on the position on the optoelectronic component (an image sensor, for example). The transmission of the filter is set by adjusting the thickness of the cavity. Thus, in operation, part of the incident light corresponding to the wavelength of the filter is transmitted through it in the form of a coloured beam, while the rest of the incident light is reflected. Generally speaking, the thickness of the dielectric layer fixes the central wavelength transmitted, while the thickness of the metal layers makes it possible to set the spectral width of transmission. Furthermore, the use of several Fabry-Perot cavities makes it possible to modify the spectral transmission profile of the filter. A filter of this type is made using conventional semiconductor manufacturing techniques. Thus, to obtain a red-green-blue filter, it is advisable to form at least one dielectric cavity whose thickness should have three different values. This entails significant technological restrictions, especially at least one step of masking and then etching each dielectric cavity made.

It has also been shown that a multispectral filter array could be used for imaging directly carried out on an optical sensor array according to a CMOS-compatible manufacturing technique (bottom-up approach).

More recently, document GB2574805 has also described feasibility of optically functional devices following the creation of Fabry-Perot cavities above a CMOS image sensor device using a so-called grayscale lithography technique. The method for manufacturing the multispectral filter in this document is based on the following steps of:
Depositing a first metal layer onto a substrate including CMOS type photoelectric transducers;
Structuring a layer of resist by Grayscale lithography so as to create a plurality of resist patterns, each pattern forming a Fabry-Perot cavity;
Depositing a second layer of metal onto the patterns.

The latter solution also has some drawbacks. The first of these consists in carrying out Grayscale lithography on a stack already including a metal layer: a reflection phenomenon at the metal-resist interface is then likely to greatly affect control on the resist thickness during lithography. Furthermore, Grayscale lithography makes it possible to obtain resist pattern thicknesses of at least 40 or 50 nm: such a value is sufficient in the visible range, but it may be necessary to obtain lower thicknesses to filter lower wavelengths in other spectral ranges. Such thicknesses of less than 40-50 nm are difficult to obtain using Grayscale lithography as described in document GB2574805.

### SUMMARY

An aspect of the invention offers a solution to the problems discussed previously, by providing a method for manufacturing a multispectral filter for electromagnetic radiation that makes it possible to better control thicknesses of Fabry-Perot cavities and to obtain Fabry-Perot cavity thicknesses of less than 40 nm.

To do this, an aspect of the invention is a method for manufacturing a multispectral filter for electromagnetic radiation, said filter including at least two colour filters, each filter including a first reflective layer, a second reflective layer, a layer of Fabry-Perot cavity dielectric material between the first reflective layer and the second reflective layer, the thickness of the dielectric layer of the two colour filters being different and each of the two filters facing a photoelectric transducer, said method including the following steps of:
Depositing a layer of structuring material onto a carrier substrate including at least two photoelectric transducers;
Three-dimensionally structuring the layer of structuring material so as to obtain at least two structuring material patterns of different heights, at least one of the patterns having a maximum reference height relative to the carrier substrate, the height being measured perpendicularly to the plane of the substrate, each of the patterns facing a photoelectric transducer;
Conformally depositing a first reflective layer onto the at least two structuring material patterns;
Depositing a layer made of the dielectric material intended to form the dielectric patterns of the Fabry-Perot cavities, said layer of dielectric material covering all the patterns by having an upper surface, each point of which is located at a height greater than the maximum reference height;
Planarising the dielectric material by removal with a selective stop at the top of the highest structuring material pattern covered by the reflective layer;
Depositing a layer made of the same dielectric material so as to complete formation of the Fabry-Perot cavities;
Depositing a second reflective layer onto the at least two Fabry-Perot cavities.

By virtue of an aspect of the invention, the Fabry-Perot cavities are made with a structuring step, for example via Grayscale lithography, carried out before the step of depositing the first reflective layer. This characteristic avoids drawbacks related to the reflection phenomenon at the metal-resist interface. Furthermore, the thickness of the cavity of lowest thickness is directly set by the thickness of the dielectric layer made during the second deposition of dielectric material directly onto the first reflective layer. Indeed, this deposition is preceded by a planarisation step with a stop at the top of the structuring material pattern covered by the reflective layer: thus, it is the thickness of the second layer of dielectric material that makes it possible to fix the lowest thickness of the Fabry-Perot cavity. By proceeding in this way, the method according to an aspect of the invention dispenses with the thickness control limits related to Grayscale lithography, and makes it possible, using conventional deposition techniques, to achieve much lower thicknesses than known solutions, especially of less than 40 nm. Finally, it should be noted that the method according to an aspect of the invention applies to any type of substrate, whether a substrate integrating CMOS photodetectors or a transparent substrate, for example made of glass, the photodetectors being disposed under the substrate, for example. As such, by “carrier substrate”, it is meant both the substrate and the photoelectric transducers, whether the latter are integrated into the substrate or above or below said substrate.

By “photoelectric transducers”, it is meant devices that can operate either as collectors of light from the filters or as transmitters of light to the filters. When they are collectors, the transducers can be CMOS-type photodiodes, for example. When they are transmitters, the transducers can be LED diodes, QLED type diodes or LASER diodes, in which case the transmitters have a wider emission spectrum than that of the corresponding Fabry-Perot cavities.

Further to the characteristics just discussed in the previous paragraph, the method may have one or more of the following additional characteristics, considered individually or according to any technically possible combinations:
According to a first embodiment, the structuring material is a resist, said structuring step being carried out by a so-called grayscale lithography step on the layer of structuring material followed by a step of crosslinking the resist; beneficially, the structuring step is followed, before the step of conformally depositing the first reflective layer onto the at least two structuring material patterns, by a step of conformally depositing an encapsulation layer onto the at least two structuring material patterns, said first reflective layer covering the encapsulation layer;
According to a second embodiment, said structuring material is an organic or inorganic isolating material, said structuring step including the following sub-steps of:
   Depositing a layer of resist following the step of depositing the layer of organic or inorganic isolating material;
   So-called Grayscale lithographing on the layer of resist so as to three-dimensionally structure the layer of resist in order to obtain at least two resist patterns of different heights;
   Transferring the two resist patterns into the layer of organic or inorganic material so as to obtain said at least two structuring material patterns of different heights.
depositing the layer made of the dielectric material intended to form the dielectric patterns of the Fabry-Perot cavities and depositing a layer made of the same dielectric material so as to complete formation of the Fabry-Perot cavities are conformal depositions;
the step of three-dimensionally structuring the layer of structuring material is a step of obtaining at least two structuring material patterns of different heights having a void space between said at least two structuring patterns.
According to a first alternative, the method according to the invention includes, after the step of conformally depositing the first reflective layer and before depositing the layer made of the dielectric material intended to form the dielectric patterns of the Fabry-Perot cavities, the following steps of:
   Depositing a layer, called an isolation layer, said isolation layer covering all the structuring material patterns by having an upper surface, each point of which is located at a height relative to the carrier substrate greater than the maximum reference height;
   Depositing a layer of resist above said isolation layer;
   Removing the resist so as to retain the resist only above the void space(s) between the structuring material patterns and leave the isolation layer apparent above the structuring material patterns;
   Removing the material of the isolation layer from the apparent zone of the isolation layer;
   Removing the remaining resist in order to retain walls made of said material of the isolation layer between the structuring material patterns.
According to a second alternative, the method according to the invention includes, after the step of conformally depositing the first reflective layer and before depositing the layer made of the dielectric material intended to form the dielectric patterns of the Fabry-Perot cavities, the following steps of:
   Depositing a layer of resist covering all the structuring material patterns by having an upper surface, each point of which is located at a height relative to the carrier substrate greater than the maximum reference height;
   Removing the resist between the structuring material patterns so as to retain the resist only above the structuring material patterns;
   Depositing a layer, called the isolation layer, said isolation layer covering all the structuring material patterns covered by resist and filling the spaces between said patterns, by having an upper surface each point of which is located at a height relative to the carrier substrate greater than the maximum reference height;
   Removing the material of the isolation layer above the structuring material patterns and the remaining resist in order to retain walls made of said material of the isolation layer between the structuring material patterns;
said material of the isolation layer may be a sacrificial material; said method then including the following steps of:
   Depositing a layer of resist onto the second reflective layer;
   Removing the resist from the zones above the space(s) between the structuring material patterns;
   Removing the material of the second reflective layer, the dielectric material intended to form the dielectric patterns of the Fabry-Perot cavities and the sacrificial material from the zones above the space(s) between the structuring material patterns so as to form void walls between the structuring material patterns and between the overhanging Fabry-Perot cavities;
   Removing the remaining resist.
said material of the isolation layer may also be a low or high optical index dielectric material; by high or low optical index material, it is meant a material having an optical refractive index strictly lower than or strictly higher than the refractive index of the resist or of the material of the sub-layer and the refractive index of the dielectric material intended to form the dielectric patterns of the Fabry-Perot cavities; said method then includes the following steps of:
   Depositing a layer of resist onto the second reflective layer;
   Removing the resist from the zones above the space(s) between the structuring material patterns;
   Removing the material of the second reflective layer and the dielectric material from the zones not protected by the remaining resist so as to reach the low or high optical index dielectric material;
   Depositing a layer of the low or high optical index dielectric material above the remaining resist supplementing the dielectric material already present between the structuring material patterns so as to fill the void between the overhanging Fabry-Perot cavities;
   Removing the resist and the low or high optical index dielectric material above the resist zones, leaving the low or high optical index material between the structuring material patterns and between the overhanging Fabry-Perot cavities, so as to form dielectric isolation walls.

The invention and its different applications will be better understood upon reading the following description and upon examining the accompanying figures.

### BRIEF DESCRIPTION OF THE FIGURES

The figures are set forth by way of indicating and in no way limiting purposes of the invention.

FIG. 1 illustrates the different steps of the method according to a first embodiment of the invention;

FIG. 2 illustrates the different steps of the method according to a second embodiment of the invention;

FIG. 3, FIG. 4, FIG. 5, FIG. 6, FIG. 7, FIG. 8 and FIG. 9 illustrate the different steps of two alternatives to the method according to the invention ensuring optical isolation between the pixels as well as between the Fabry-Perot cavities.

### DETAILED DESCRIPTION

The figures are set forth by way of indicating and in no way limiting purposes of the invention.

It should be born in mind that, generally speaking and well known to those skilled in the art, a metal/dielectric type colour filter made from a Fabry-Perot cavity is obtained by dimensioning the thickness of the dielectric layer formed between the two metal layers. If several colours are to be filtered on a same component, it is then necessary to be able to obtain a dielectric of variable thickness on the same component.

This dimensioning is carried out, for example, using an electromagnetic calculation program such as the Abeles matrix transfer formalism or a diffraction calculation for pixels whose size is close to the wavelength such as the formalism of the Fourier Expansion Modal Method or Rigorous Coupled Wave Analysis (RCWA).

These calculation programs enable the optimum parameters for the dielectric metal stacks to be determined for each pixel. The calculation especially takes account of the thicknesses of the metal and dielectric layers as well as their indices, the spectrum and the angular distribution of the incident light. For example, in the case of Fabry-Perot filters, the central wavelength of the filter is approximately determined by the following formula:

$${λ}_{res} = \frac{2 hn . cos θ}{m - \frac{{ϕ}_{1} + {ϕ}_{2}}{2 π}}$$

where
h is the thickness of the cavity, that is, approximately the thickness of the dielectric layer
m, a positive integer between 1 and 10, is the order of the cavity,
n is the effective index of the cavity, and
φ1 and φ2 are the reflection phase shifts on the metal mirrors (determined by the nature of the materials involved and the wavelength considered),
θ is the angle of incidence of the incident light on the filter (counted from the perpendicular to the filter surface).

Once the order of the cavity has been chosen, the angle of attack known and the index and phase shifts known, all that remains is to determine an approximate thickness h so that the cavity is centred on a particular wavelength. Once the filter function has been calculated for each filter and each wavelength, the thicknesses h of the dielectrics are then adjusted according to the performance required (search for a good signal-to-noise ratio, maximum transmission, etc.).

Another, more empirical method consists in calculating the response of the stack for several thicknesses h and choosing h such that the filter resonance peak (λres) is positioned in accordance with the specifications.

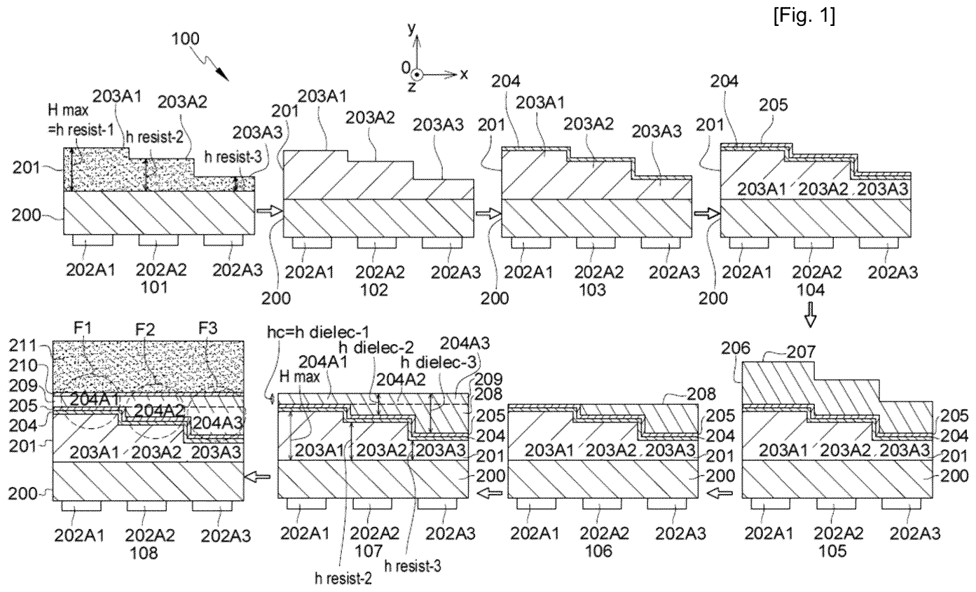

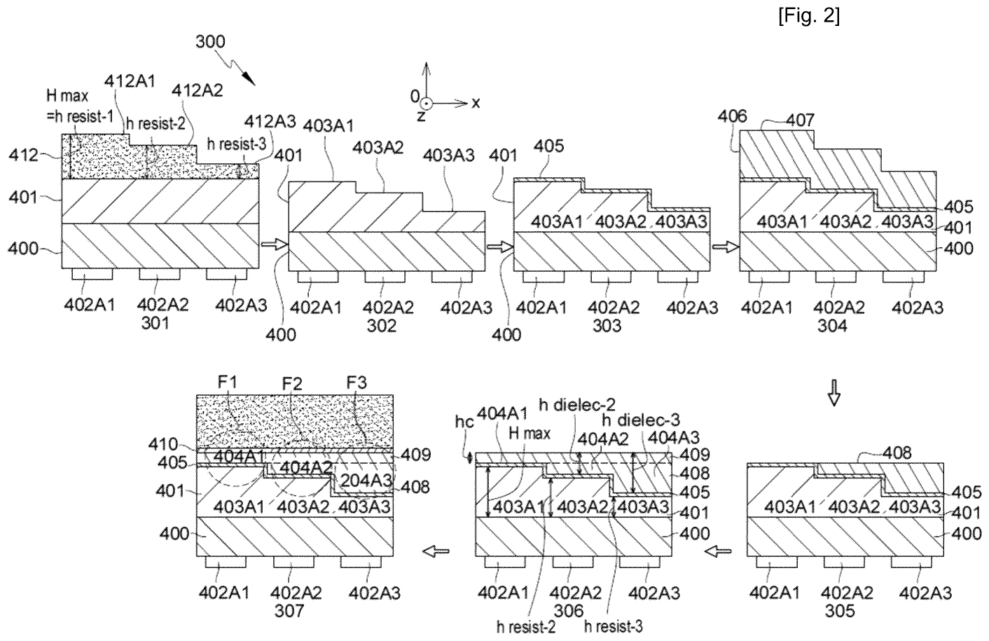

FIG. 1 illustrates the different steps of a method 100 according to a first embodiment of the invention in which no isolation is provided either between the Fabry-Perot cavities or between the photoelectric transducers.

The first step 101 of the method 100 consists in depositing a layer of resist 201 onto a substrate 200, called the carrier substrate, then in three-dimensionally structuring said layer of resist 201. The substrate 200 may, for example, be a Si substrate, a Silicon On Isolator (SOI) substrate or a glass or sapphire substrate.

The carrier substrate 200 includes a plurality of (at least two) photoelectric transducers 202Ai (here 3 photoelectric transducers 202A1, 202A2, and 202A3 are represented). The transducers 202Ai are here schematically represented under the substrate 200, it being understood that they could be formed inside the latter or above it. According to an embodiment of the invention, the photoelectric transducers 202Ai are considered an integral part of the carrier substrate 200. The photoelectric transducers can operate either as collectors of light from the filters or as transmitters of light to the filters. When they are collectors, the transducers can be CMOS-type photodiodes, for example. When they are transmitters, the transducers can be LED diodes, QLED type diodes or LASER diodes, in which case the transmitters have a wider emission spectrum than that of the corresponding Fabry-Perot cavities.

The 3D structuring of the layer of resist 201 is carried out by a lithography step. This lithography can be, in an embodiment, grayscale lithography according to electronic or optical terminology. Other lithography techniques such as two-photon lithography or nanoimprint lithography can also be used to make the resist structure 201. The structure 201 includes a plurality of 3D patterns 203Ai (here 3 patterns 203A1, 203A2, and 203A3). It is possible to freely fix the dimensions of each pattern in the three directions of space Oxyz (where Oxy is the plane of the figure, the axis Oy being along the direction perpendicular to the plane of the substrate 200 and the axis Oz being along the direction perpendicular to the plane of the figure).

According to an aspect of the invention, it is advisable to have at least two resist patterns 203Ai of different heights (here the 3 patterns each have different heights). Of all these patterns 203Ai, one of them, in this case the pattern 203A1, has a maximum height Hmax, called the reference height, the height being measured perpendicularly to the plane of the substrate 200 along the axis Ox. More generally, the height of the pattern 203Ai will be denoted as hᵣₑₛᵢₛₜ₋ᵢ. Thus, in FIG. 1, Hmax is equal to hᵣₑₛᵢₛₜ₋₁. Each pattern 203Ai faces the corresponding transducer 202Ai along the axis Oy.

The method 100 then includes a step 102 of crosslinking the layer of resist 201 structured in order to densify the latter by stabilising the Grayscale resist using a thermal or ultraviolet method.

Beneficially, the method 100 according to an embodiment of the invention includes a third step 103 consisting in performing a conformal deposition of a thin encapsulation layer 204 (a few tens of nm) onto the resist patterns 203Ai (above and onto the flanks of the patterns 203Ai). The material of the encapsulation layer 204 may be, for example, an oxide of the Al2O3 or SiO2 type or a nitride, and the deposition will be carried out by a low-temperature deposition technique such as Atomic Layer Deposition (ALD).

The method 100 according to an embodiment of the invention then includes a step 104 of depositing a reflective layer 205, for example with a thickness of between and 100 nm, covering the encapsulation layer 204 above the resist patterns 203Ai. This reflective layer 205, typically a metal layer, forms the first reflective layer of the Fabry-Perot cavity type colour filters to come. The reflective layer 205 is conformally deposited by Chemical Vapour Deposition (CVD) or Physical Vapour Deposition (PVD). The layer 205 is deposited continuously onto all the resist patterns 203Ai covered by the encapsulation layer, including onto the flanks of the latter. Conformal deposition enables the thickness of the reflective layer 205 to be constant, at least on the top of the patterns but also on the flanks of the patterns 203Ai.

The following step 105 consists in depositing a layer 206 made of the dielectric material intended to form the dielectric patterns of the Fabry-Perot cavities. The layer 206 of dielectric material covers all the resist patterns 203Ai covered by the encapsulation layer 204 and the reflective layer 205. The layer 206 has an upper surface 207 (not necessarily planar), each point of which is located at a height, relative to the carrier substrate 200, greater than the maximum reference height Hmax. The material of the layer 206 is desirably, but not restrictively, a material that is transparent in the visible range, such as an organic material of the polymer or inorganic type (oxide, silicon nitride, alumina, etc.). The deposition is, in an embodiment, a conformal deposition carried out, for example, by a Physical Vapour Deposition (PVD) or Chemical Vapour Deposition (CVD) or Low Pressure Chemical Vapour Deposition (LPCVD) or Plasma Enhanced Chemical Vapour Deposition (PECVD) technique. It should be noted that the invention is not limited to the visible range and that other materials transparent to other wavelengths, in the infrared for example (using silicon for example), can be used.

The method 100 then includes a step 106 of planarising the layer 206 made of the dielectric material intended to form the dielectric patterns of the Fabry-Perot cavities so as to form a layer 208 planarised at the surface by removing the dielectric material from the layer 206. The planarisation step may be carried out by an etching step of the etch-back type and/or a Chemical Mechanical Polishing (CMP) step. Planarisation is performed with a stop on the reflective layer 205 located at its highest level (that is, at the reference height of the pattern 203A1).

The method 100 according to an embodiment of the invention then includes a step 107 of conformally depositing a layer 209 of the same dielectric material intended to form the dielectric patterns of the Fabry-Perot cavities as during step 105. This step is carried out, for example, by a Physical Vapour Deposition (PVD) or Chemical Vapour Deposition (CVD) or Low Pressure Chemical Vapour Deposition (LPCVD) or Plasma Enhanced Chemical Vapour Deposition (PECVD) technique. The height of the layer 209 is denoted as hc, the height being measured perpendicularly to the plane of the substrate. After this step, a plurality of Fabry-Perot cavity dielectric patterns 204Ai are obtained (here three patterns 204A1, 204A2 and 204A3).

For each resist pattern 204Ai, the height of the pattern is denoted as hdiel_i, the height being measured perpendicularly to the plane of the substrate. The height hdiel_i of the pattern 204i can be determined according to the methods mentioned above (based on the specifications for the desired filtering). According to the method 100 according to an embodiment of the invention, the height hdiel_i is set by the following formula: hdiel_i=Hmax−hᵣₑₛᵢₛₜ₋ᵢ+hc.

Thus, for the pattern 204A1, hdiel_1 is here directly equal to the height hc of the layer 209.

More generally, for each pattern 204Ai, the height is determined technologically by the difference in height between that of the highest resist pattern 203A1 Hmax and the height of the resist pattern 203Ai to which is added the height of the second dielectric layer 209. It can thus be observed that the height of the Fabry-Perot cavity dielectric patterns 204Ai is not related to the thickness of the layer of resist 201 (unlike solutions in the state of the art, which make it difficult to obtain thicknesses of around ten nm) but to the difference in height between the patterns. Such a configuration makes it possible to achieve much smaller heights. This is particularly true for the Fabry-Perot cavity dielectric pattern 204A1 formed directly above the highest resist pattern 203A1, which depends only on the height of the second dielectric layer 209, which is very easy to control and can reach values in the order of 10 nm.

Step 108 of the method 100 then consists in depositing a second reflective layer 210, for example with a thickness of between 20 and 50 nm, covering the second dielectric layer 209 above the Fabry-Perot cavity patterns 204Ai. This planar reflective layer 210 forms the second reflective layer of the Fabry-Perot cavity-type colour filters. The reflective layer 210 is conformally deposited by Chemical Vapour Deposition (CVD) or Physical Vapour Deposition (PVD). A plurality (here 3) of Fabry-Perot cavity-type colour filters Fi (that is, F1, F2 and F3) are thus obtained, each formed by the first reflective layer 205, the pattern 204Ai and the second reflective layer 210.

Optionally, it is also possible to deposit a layer 211 according to CMOS technology onto the second reflective layer 210.

FIG. 2 illustrates the different steps of a method 300, an alternative to the method 100 of FIG. 1, wherein no isolation is provided either between the Fabry-Perot cavities or between the photoelectric transducers.

The first step 301 of the method 300 consists in depositing, onto a substrate 400, called the carrier substrate, a layer of material such as an organic material of the polymer or inorganic type (oxide, silicon nitride, alumina, etc.), called the sub-layer 401. The substrate 400 is of the same type as the substrate 200 of FIG. 1 and includes a plurality of (at least two) photoelectric transducers 402Ai (here 3 photoelectric transducers 402A1, 402A2, and 402A3 are represented). A layer of resist 412 is then deposited onto the sub-layer 401. The layer of resist 412 is then three-dimensionally structured. The 3D structuring of the layer of resist 412 is carried out by a lithography step. This lithography can, in an embodiment, be grayscale lithography according to electronic or optical terminology. Other lithography techniques such as two-photon lithography or nanoimprint lithography may also be used to make the resist structure 412. The structure 412 includes a plurality of 3D patterns 412Ai (here 3 patterns 412A1, 412A2, and 412A3). It is possible to freely fix the dimensions of each pattern in the three directions of space Oxyz (where Oxy is the plane of the figure, the axis Oy being along the direction perpendicular to the plane of the substrate 400 and the axis Oz being along the direction perpendicular to the plane of the figure).

According to an embodiment of the invention, it is advisable to have at least two resist patterns 412Ai of different heights (here the 3 patterns each have different heights). Of all these patterns 412Ai, one of them, in this case the pattern 412A1, has a maximum height Hmax, called the reference height, the height being measured perpendicularly to the plane of the substrate 400 along the axis Ox. More generally, the height of the pattern 412Ai will be denoted as hᵣₑₛᵢₛₜ₋ᵢ. Thus, in FIG. 2, Hmax is equal to hᵣₑₛᵢₛₜ₋₁. Each pattern 412Ai faces the corresponding transducer 202Ai along the axis Oy.

The method 300 then includes a step 302 of transferring the patterns 412Ai from the layer of resist 412 structured into the sub-layer 401: in other words, at the end of this step 302, the layer of resist 412 structured is removed and transferred entirely into the sub-layer 401 so that the sub-layer 401 is itself three-dimensionally structured with a plurality of patterns 403Ai (here three patterns 403A1, 403A2 and 403A3) of dimensions similar to the dimensions of the patterns 412Ai. This transfer step can be carried out according to techniques known to the person skilled in the art, such as dry etching or wet etching.

Step 302 is followed by a step 303 of depositing a reflective layer 405, for example with a thickness of between 20 and 50 nm, covering the patterns 403Ai of the structured sub-layer 401. This reflective layer 505 forms the first reflective layer of the Fabry-Perot cavity type colour filters to come. The reflective layer 505 is conformally deposited by Chemical Vapour Deposition (CVD) or Physical Vapour Deposition (PVD). The layer 405 is deposited continuously onto all the patterns 403Ai, including onto the flanks of the latter. Conformal deposition enables a thickness of the reflective layer 405 to be constant, at least on the top of the patterns but also, in an embodiment, on the flanks of the patterns 403Ai. It should be noted that, unlike the first embodiment in FIG. 1, it is entirely possible here to dispense with the deposition of an encapsulation layer. As with the first exemplary embodiment in FIG. 1, the structuring step, using Grayscale lithography for example, is carried out before the step of depositing the first reflective metal layer.

The benefit of having patterns not made of resist but of another organic or inorganic material lies in the fact that the resist is often a polymer resist which can have characteristics that degrade over time, leading to a change in colour or loss of light transmission. The use of an organic material provides better stability over time and the use of an organic material prevents the colour from changing over time.

Steps 304 to 307 of the method 300 according to an embodiment of the invention are identical to steps 105 to 108 of the method 100 according to an embodiment of the invention.

Thus, the next step 304 consists in depositing a layer 406 made of the dielectric material intended to form the dielectric patterns of the Fabry-Perot cavities. The layer 406 of dielectric material covers all the patterns 403Ai covered by the reflective layer 405. The layer 406 has an upper surface 407 (not necessarily planar), each point of which is located at a height, relative to the carrier substrate 400, greater than the maximum reference height Hmax. The material of the layer 406 is desirably, but not restrictively, a transparent material in the visible range, such as an organic material of the polymer or inorganic type (oxide, silicon nitride, alumina, etc.). The deposition is, in an embodiment, a conformal deposition, for example carried out by a Physical Vapour Deposition (PVD) or Chemical Vapour Deposition (CVD) or Low Pressure Chemical Vapour Deposition (LPCVD) or Plasma Enhanced Chemical Vapour Deposition (PECVD) technique.

The method 400 then includes a step 305 of planarising the layer 406 made of the dielectric material intended to form the dielectric patterns of the Fabry-Perot cavities so as to form a layer 408 planarised at the surface by removal of the dielectric material from the layer 406. Planarisation is performed with a stop on the reflective layer 405 located at its highest level (that is, at the reference height of the pattern 403A1).

The method 300 according to an embodiment of the invention then includes a step 306 of conformally depositing a layer 409 of the same dielectric material intended to form the dielectric patterns of the Fabry-Perot cavities as during step 304. This step is carried out, for example, by a PVD, CVD, LPCVD or PECVD deposition technique. The height of the layer 409 is denoted as hc, the height being measured perpendicularly to the plane of the substrate. After this step, a plurality of Fabry-Perot cavity dielectric patterns 404Ai (here three patterns 404A1, 404A2 and 404A3) are obtained.

For each resist pattern 404Ai, its height hdiel_i is determined identically as for the method 100 of FIG. 1.

Step 307 of the method 300 then consists in depositing a second reflective layer 410, for example with a thickness of between 20 and 50 nm, covering the second dielectric layer 409 above the Fabry-Perot cavity patterns 404Ai. This planar reflective layer 410 forms the second reflective layer of the Fabry-Perot cavity type colour filters. The reflective layer 410 is conformally deposited by CVD or PVD deposition. A plurality (here 3) of Fabry-Perot cavity type colour filters Fi (that is, F1, F2 and F3) are thus obtained, each formed by the first reflective layer 405, the pattern 404Ai and the second reflective layer 410.

Optionally, it is also possible to deposit a CMOS layer 411 onto the second reflective layer 410.

The embodiments shown in FIGS. 1 and 2 illustrate the simple and efficient manufacture of Fabry-Perot resonant cavities. However, in the case of photoelectric transducers present in a discrete manner, that is, pixelated transducers, each pixel being formed by a photoelectric transducer (a photodetector for example) and the corresponding Fabry-Perot cavity, it may be particularly interesting to carry out optical isolation between each pixel. Indeed, when the dimensions of the pixels and therefore of the colour filters are reduced, typically to the order of the wavelength of the light, the spatial overlap of light contributions from one Fabry-Perot cavity to another can degrade the efficiency of the overall device. This “crosstalk” phenomenon has already been observed in photoelectric transducers (that is, CMOS sensors). In recent years, pixel dimensions have continued to decrease in order to provide high-resolution sensors, especially for smartphones. This reduction in pixel dimensions has two very distinct consequences:
The total amount of incident light impinging on each pixel decreases, meaning that fewer and fewer photons reach the photosensitive component. Collecting and guiding each photon within the component towards the sensor is all the more important to guarantee the sensor's efficiency.
When the pixel size approaches the length of the light to be collected, diffraction comes into play, increasing optical and spatial losses in the device.

In addition to the problems associated with reducing pixel dimensions, the angle of incidence at which light penetrates the Fabry-Perot cavity is also an element that should not be overlooked. Indeed, when oblique light rays reach the surface of the cavities, some of the light passes through the physical border of the filter and ends up in the neighbouring cavity. This unwanted, parasitic contribution distorts the collection of light at the scale of the device, and is another major source of “crosstalk” from one pixel to another.

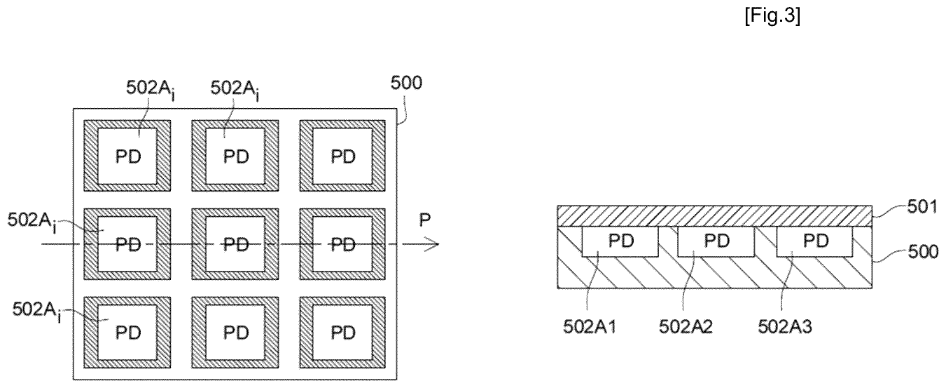

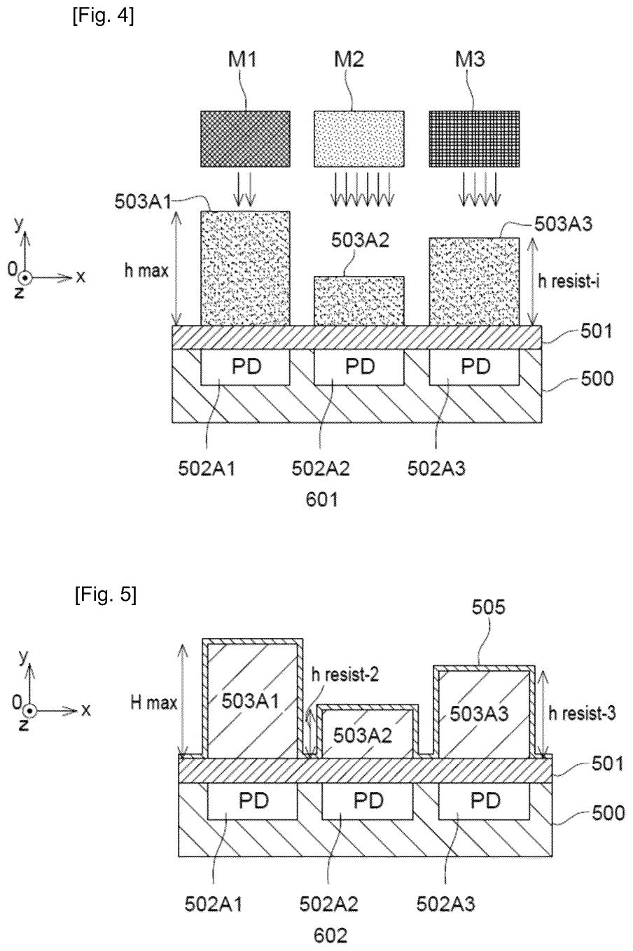

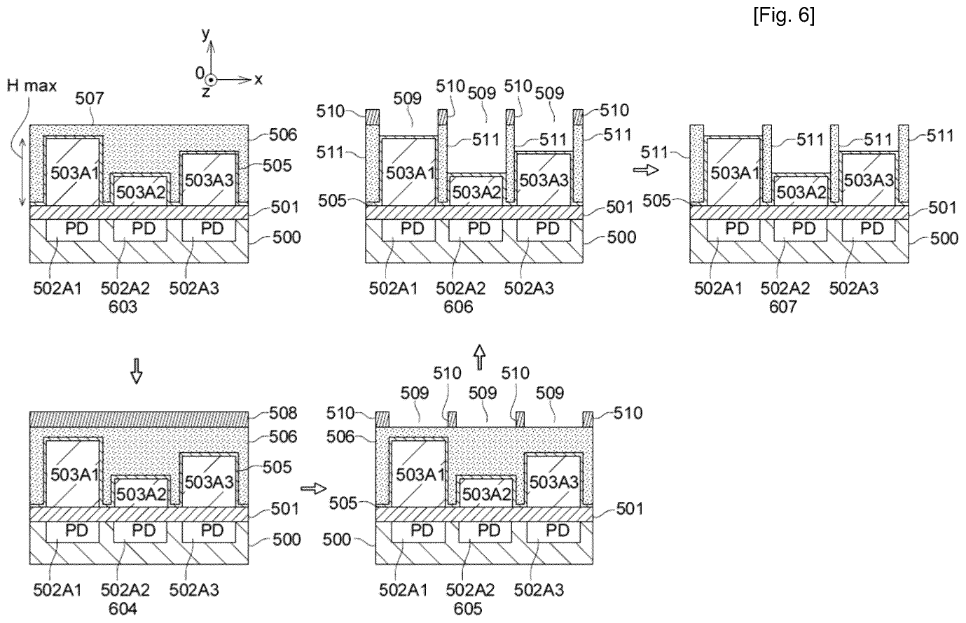

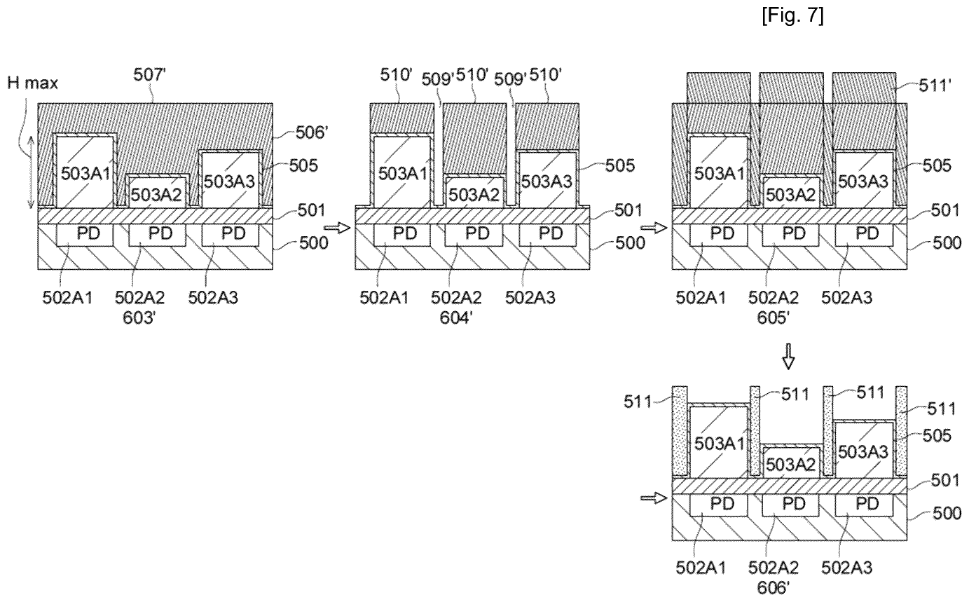

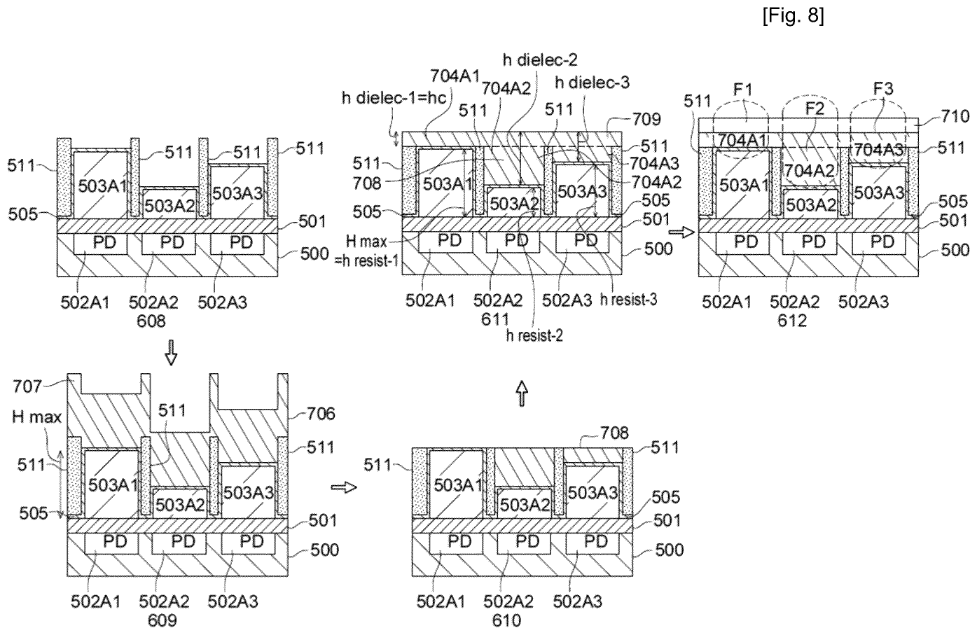

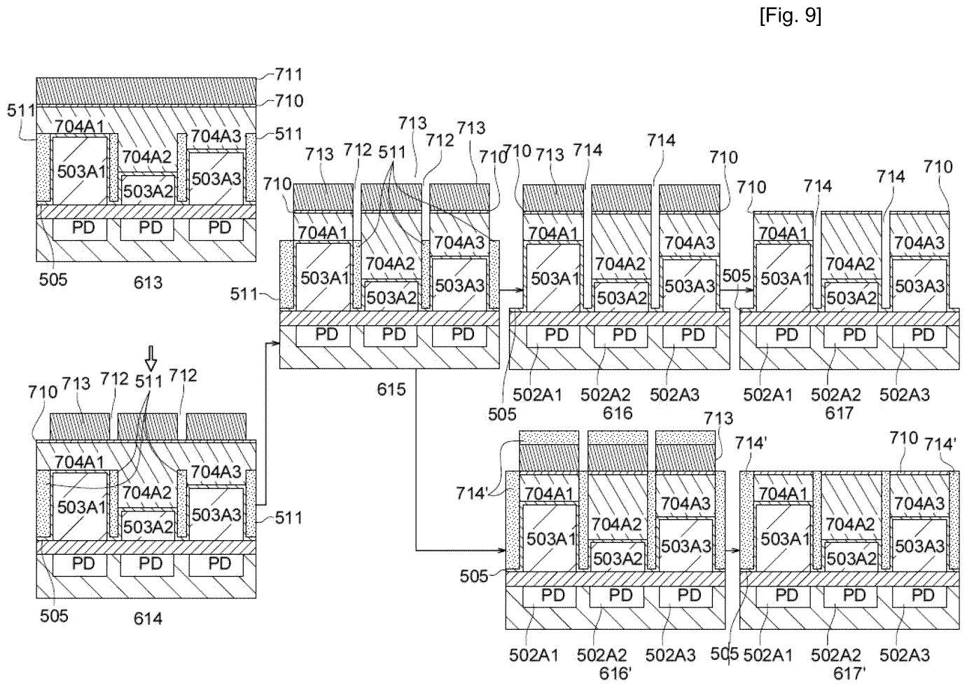

FIG. 3 schematically shows a carrier substrate 500 in top view and in cross-section along the plane P perpendicular to the plane of the substrate 500 and intersecting the photoelectric transducers. The carrier substrate 500 includes a plurality of pixelated photoelectric transducers 502Ai disposed in the form of a matrix (here a 3×3 matrix) in the substrate 500 (three of which 502A1, 502A3 and 502A3 are represented in cross-section) included in the substrate 500. The substrate 500 is covered by a barrier layer 501.

Now will be described different alternatives to the method according to an embodiment of the invention enabling colour filters to be made, each associated with a transducer located above or in the substrate 500, with optical isolation enabling crosstalk to be reduced, not only between the pixelated photoelectric transducers but also between the Fabry-Perot cavities.

The first step 601 illustrated in FIG. 4 and common to these alternatives consists in making resist patterns 503Ai of different heights, hereinafter called pillars (here three pillars 503A1, 503A2 and 503A3), above the barrier layer 501, it being understood that these pillars could be made directly on the substrate 500. To do this, a layer of resist is first deposited, which is then three-dimensionally structured by Grayscale lithography using masks M1, M2 and M3 of different densities. The exposure of the resist is thus different and, after development, the three pillars 503Ai of different heights are obtained, the resist between the pillars being completely removed so that there is a void space between each pillar 503Ai.

As in the case of FIGS. 1 and 2, it is advisable to have at least two resist pillars 503Ai of different heights (here the 3 pillars are each of different heights). Of all these pillars 503Ai, one of them, in this case the pillar 503A1, has a maximum so-called reference height Hmax, the height being measured perpendicularly to the plane of the substrate 500 along the axis Ox. More generally, the height of the pillar 503Ai will be denoted as hᵣₑₛᵢₛₜ₋ᵢ. Thus, in the figure, Hmax is equal to h_{resist_1}. Each pillar 503Ai faces the corresponding transducer 502Ai along the axis Oy. As in FIG. 1, the resist pillars 503i are crosslinked in order to densify them.

It should be noted that the pillars 502Ai in FIG. 4 are made of resist but could also be made of an organic or inorganic material by means of a sub-layer as set forth with reference to FIG. 2 by transferring resist patterns into the sub-layer.

The following step 602 illustrated in FIG. 5 is also common to these alternatives to the method according to an embodiment of the invention and corresponds to steps 103-104 and 303 of FIGS. 1 and 2. Indeed, the aim is either to deposit an encapsulation layer and then a reflective layer onto the pillars 502Ai when the latter are made of resist or simply a reflective layer onto the pillars 502Ai when the latter are made of organic or inorganic material. For the sake of simplicity, the encapsulation layer and the reflective layer (in the case of resist pillars) or the reflective layer (in the case of pillars of the sub-layer) are represented by a single layer 505 in FIG. 5, hereinafter referred to by the generic term “reflective layer”. The techniques for making this layer are similar to those already set forth with reference to FIGS. 1 and 2. The thickness of the reflective layer varies between around ten nanometres and a few hundred nanometres depending on the metal chosen and the design choices made.

FIG. 6 illustrates the steps 603 to 607 of a first alternative embodiment for achieving optical isolation between adjacent pixels (that is, between the photoelectric transducers 502Ai and between the pillars 503Ai of resist or undercoating material).

Step 603 consists in depositing a layer, called the isolation layer 506. This substantially planar isolation layer covers all the pillars 503Ai covered by the reflective layer 505 and has an upper surface 507, each point of which is located at a height relative to the carrier substrate greater than the maximum reference height Hmax. As will be seen later, the isolation layer 506 may be made of a sacrificial material (that is, intended to disappear) or, on the contrary, of a high optical index or low optical index material intended to provide isolation between the photoelectric transducers 502Ai. By a high or low optical index material, it is meant a material having an optical refractive index strictly lower or strictly higher than the refractive index of the resist or of the material of the sub-layer and than the refractive index of the dielectric material intended to form the dielectric patterns of the Fabry-Perot cavities.

A material such as SiN can be used for high optical index materials, and polymers containing fluorine groups can be used for low optical index materials. It will be seen later that when the material used is a sacrificial material, the aim is to create air-gaps to achieve isolation.

Step 604 consists in depositing a layer of photo- or electron-sensitive resist 508 above the isolation layer 506.

Step 605 then consists in making gaps 509 aligned with the borders of the pillars 503Ai. To do this, the layer of photo- or electron sensitive resist 508 is exposed using lithography equipment, so as to define a regular gap grid on its surface after the resist has developed. The lithography used here is conventional lithography. The gaps 509 are created after removal of the resist leaving lines of resist 510 above the layer 506 of isolation material in the zone located between each pillar 503Ai.

According to step 606, in the open spaces in the resist formed by the gaps 509, the isolation material is etched with a stop on the reflective layer 505. At the end of this step 606, borders or walls 511 of isolating material remain on the respective edges of each pillar 503Ai, line of resist 510 extending from each border 511.

The next step 607 then consists in removing (by etching or stripping type technology) the lines of resist 510 so as to leave only the borders or walls 511 of isolating material on each side of the pillars 503Ai filling the void space between the pillars 503Ai. The walls 511 can act as optical isolators between adjacent pixels. They can also act as containment walls for pillars of resist or sub-layer material. The walls will also prevent deformation of pillars of resist or sub-layer material during the planarisation step to come.

FIG. 7 illustrates steps 603′ to 606′ of a second alternative embodiment of optical isolation between adjacent pixels (that is, between photoelectric transducers 502Ai and between patterns 503Ai of resist or sub-layer material).

Step 603′ consists in depositing a layer of photo- or electron sensitive resist 506′. This layer of resist 506′ covers all the pillars 503Ai covered by the reflective layer 505 and has an upper surface 507′, each point of which is located at a height relative to the carrier substrate greater than the maximum reference height Hmax.

Step 604′ then consists in making gaps 509′ creating void spaces between each pillar 503Ai. To do this, the layer of photo- or electron sensitive resist 507′ is exposed using lithography equipment, in order to define a regular gap grid on its surface after the resist has developed. The lithography used here is conventional lithography. The gaps 509′ are created after removal of the resist, leaving resist 510′ above each pillar 503Ai.

According to the next step 605′, a layer called the isolation layer 511′ is deposited. This isolation layer 511′ covers all the resist 510′ and fills the gaps 509′ to a height strictly greater than Hmax. As in the case of FIG. 6, the isolation layer 511′ may be made of a sacrificial material (that is, intended to disappear) or, on the contrary, of a high optical index or low optical index material intended to ensure isolation between the photoelectric transducers 502Ai.

Step 606′ then consists in removing the resist 510′ as well as the material of the isolation layer 511′ located above the resist 510′, for example by etching or stripping techniques, so as to leave only walls 511 of isolating material on each side of the pillars 503Ai filling the void space between said pillars 503Ai. It can be noticed that the structure obtained after steps 603′ to 606′ of FIG. 7 is identical to that obtained after steps 603 to 607 of FIG. 6.

Based on the structure obtained at the end of step 607 of FIG. 6 or step 606′ of FIG. 7, FIG. 8 illustrates steps 608 to 612 enabling Fabry-Perot cavities to be made. It should be noted that these steps 609 to 612 are substantially the same as steps 105 to 108 and 304 to 307 of FIGS. 1 and 2.

Step 608 thus consists in using the structure obtained at the end of step 607 of FIG. 6 or step 606′ of FIG. 7.

The next step 609 consists in depositing a layer 706 made of the dielectric material intended to form the dielectric patterns of the Fabry-Perot cavities. The layer 706 of dielectric material covers all the pillars 503Ai covered by the reflective layer 505. The layer 706 has an upper surface 707 (not necessarily planar), each point of which is located at a height, relative to the carrier substrate 500, greater than the maximum reference height Hmax. The material of layer 706 is desirably, but not restrictively, a material that is transparent in the visible range, such as an organic material of the polymer or inorganic type (oxide, silicon nitride, alumina, etc.). The deposition is, in an embodiment, a conformal deposition, for example carried out by a PVD, CVD, LPCVD or PECVD deposition technique.

The method then includes a step 610 of planarising the layer 706 made in the dielectric material intended to form the dielectric patterns of the Fabry-Perot cavities so as to form a layer 708 planarised at the surface by removal of the dielectric material from the layer 706. Planarisation is performed with a stop on the reflective layer 505 located at its highest level (that is, at the reference height of the pillar 503A1).

The method according to an embodiment of the invention then includes a step 611 of conformally depositing a layer 709 of the same dielectric material intended to form the dielectric patterns of the Fabry-Perot cavities as during step 609. The height of the layer 709 is denoted as hc, the height being measured perpendicularly to the plane of the substrate. After this step, a plurality of Fabry-Perot cavity dielectric patterns 704Ai (here three patterns 704A1, 704A2 and 704A3) are obtained.

For each dielectric pattern 704Ai, the height of the pattern is denoted as hdiel_i, the height being measured perpendicularly to the plane of the substrate. The height hdiel_i of the pattern 704i can be determined according to the methods mentioned above. According to the method according to an embodiment of the invention, the height hdiel_i is set by the following formula: hdiel_i=Hmax−hᵣₑₛᵢₛₜ₋ᵢ+hc.

Thus, for the pattern 704A1, hdiel_1 is here directly equal to the height hc of layer 709.

More generally, for each pattern 704Ai, the height is determined technologically by the difference in height between that of the highest resist pattern 503A1 Hmax and the height of the resist pattern 503Ai to which is added the height of the second dielectric layer 709.

Step 612 of the method according to an embodiment of the invention then consists in depositing a second reflective layer 710, for example with a thickness of between 20 and 50 nm, covering the second dielectric layer 709 above the Fabry-Perot cavity patterns 704Ai. This planar reflective layer 710 forms the second reflective layer of the Fabry-Perot cavity-type colour filters. The reflective layer 710 is conformally deposited. A plurality (here 3) of Fabry-Perot cavity type colour filters Fi (that is, F1, F2 and F3) is thus obtained, each formed by the first reflective layer 505, the pattern 704Ai and the second reflective layer 710. It should be noted that at this stage, the photoelectric transducers 502Ai as well as the pillars 503Ai are well isolated by the walls 511, but the dielectric patterns 704Ai and thus the Fabry-Perot cavities are not completely isolated.

FIG. 9 illustrates two alternative embodiments of isolation aimed at reducing crosstalk not only between the photoelectric transducers 502Ai and the pillars 503Ai but also between the dielectric patterns 704Ai and thus the Fabry-Perot cavities.

Based on the structure obtained at the end of step 612 in FIG. 8, step 613 consists in depositing a layer of resist 711 onto the second reflective layer 711.

Step 614 then consists in making gaps 712 aligned with the walls 511. To do this, the layer of photo- or electron sensitive resist 711 is exposed using lithography equipment, so as to define a regular gap grid on its surface after the resist has developed. The lithography used here is conventional lithography. The gaps 712 are created after removal of the resist leaving lines of resist 713 above the second reflective layer 710 in the zone located above each pillar 503Ai.

According to step 615, in the open spaces in the resist formed by the gaps 712, the metal of the second reflective layer 710 is etched as well as the dielectric material used for the Fabry-Perot cavities so as to reach the walls 511.

The method can then take two different routes according to whether the material of the walls 511 is a sacrificial material or a high optical index or low optical index material intended to ensure optical isolation.

According to a first alternative in which the material of the walls 511 is a sacrificial material, the method includes a step 616 of removing the walls 511 so as to form air-gaps 714 completely isolating the photoelectric transducers 502Ai, the pillars 503Ai and the dielectric patterns 704Ai from one another and thus the Fabry-Perot cavities.

Finally, step 617 consists in removing the remaining resist 713 by stripping or etching.

According to a second alternative in which the material of the walls 511 is a high or low optical index material, the method includes a step 616′ of depositing a layer 714′ of said high or low refractive index material so as to form walls made of this material completely isolating the photoelectric transducers 502Ai, the pillars 503Ai and the dielectric patterns 704Ai and therefore the Fabry-Perot cavities.

Finally, step 617′ consists in removing the remaining resist 713 as well as the low or high optical index material located above the resist by stripping or etching.

Both the air-gaps 714 and the isolation walls 714′ ensure complete isolation of the whole Fabry-Perot cavity as well as the photoelectric transducer associated thereto. Furthermore, each pillar of resist (or made of the material of the sub-layer) onto which the first reflective layer is deposited acts as a structure which guides the light waves transmitted from the filter to the transducer or from the transducer to the filter: such an arrangement further limits the risk of crosstalk between two adjacent filters and two adjacent transducers and increases the electro-optical performance of the filters.

The articles “a” and “an” may be employed in connection with various elements, components, processes or structures described herein. This is merely for convenience and to give a general sense of the elements, components, processes or structures. Such a description includes “one or at least one” of the elements or components. Moreover, as used herein, the singular articles also include a description of a plurality of elements or components, unless it is apparent from a specific context that the plural is excluded.

It will be appreciated that the various embodiments and aspects of the inventions described previously are combinable according to any technically permissible combinations. For example, various aspects of the present disclosure may be used alone, in combination, or in a variety of arrangements not specifically described in the embodiments described in the foregoing and is therefore not limited in its application to the details and arrangement of components set forth in the foregoing description or illustrated in the drawings. For example, aspects described in one embodiment may be combined in any manner with aspects described in other embodiments.

The present invention has been described and illustrated in the present detailed description and in the figures of the appended drawings, in possible embodiments. The present invention is not however limited to the embodiments described. Other alternatives and embodiments may be deduced and implemented by those skilled in the art on reading the present description and the appended drawings.

In the claims, the term “includes” or “comprises” does not exclude other elements or other steps. The different characteristics described and/or claimed may be beneficially combined. Their presence in the description or in the different dependent claims do not exclude this possibility. The reference signs cannot be understood as limiting the scope of the invention.

1. A method for manufacturing a multispectral filter for electromagnetic radiation, said filter including at least two colour filters, each filter of the at least two colour filters including a first reflective layer, a second reflective layer, a layer of Fabry-Perot cavity dielectric material between the first reflective layer and the second reflective layer, a thickness of the dielectric layer of the two colour filters being different and each of the two filters facing a photoelectric transducer, said method comprising:
depositing a layer of structuring material onto a carrier substrate including at least two photoelectric transducers;
three-dimensionally structuring the layer of structuring material so as to obtain at least two structuring material patterns of different heights, at least one of the patterns having a maximum reference height relative to the carrier substrate, the height being measured perpendicularly to the plane of the substrate, each of the patterns facing a photoelectric transducer;
conformally depositing a first reflective layer onto the at least two structuring material patterns;
depositing a layer made of the dielectric material intended to form the dielectric patterns of the Fabry-Perot cavities, said layer of dielectric material covering all the patterns by having an upper surface, each point of which is located at a height greater than the maximum reference height;
planarising the dielectric material by removal with a selective stop at the top of the highest structuring material pattern covered by the reflective layer;
depositing a layer made of the same dielectric material so as to complete formation of the Fabry-Perot cavities;
depositing a second reflective layer onto the at least two Fabry-Perot cavities.

2. The method according to claim 1, wherein the structuring material is a resist, said structuring being carried out by grayscale lithography step on the layer of structuring material followed by a step of crosslinking the resist.

3. The method according to claim 2, wherein the structuring is followed, before the conformally depositing the first reflective layer onto the at least two structuring material patterns, by a step of conformally depositing an encapsulation layer onto the at least two structuring material patterns, said first reflective layer covering the encapsulation layer.

4. The method according to claim 1, wherein said structuring material is an organic or inorganic isolating material, said structuring step including the following sub-steps of:
depositing a layer of resist following the step of depositing the layer of organic or inorganic isolating material;
grayscale lithographing on the layer of resist so as to three-dimensionally structure the layer of resist to obtain at least two resist patterns of different heights;
transferring the two resist patterns into the layer of organic or inorganic material so as to obtain said at least two structuring material patterns of different heights.

5. The method according to claim 1, wherein the deposition of the layer made of the dielectric material intended to form the dielectric patterns of the Fabry-Perot cavities and the deposition of a layer made of the same dielectric material so as to complete formation of the Fabry-Perot cavities are conformal depositions.

6. The method according to claim 1, wherein the three-dimensionally structuring of the layer of structuring material is a step of obtaining at least two structuring material patterns of different heights having a void space between said at least two structuring patterns.

7. The method according to claim 6, further comprising, after the conformally depositing of the first reflective layer and before depositing the layer made of the dielectric material intended to form the dielectric patterns of the Fabry-Perot cavities:
depositing an isolation layer, said isolation layer covering all the structuring material patterns by having an upper surface, each point of which is located at a height relative to the carrier substrate greater than the maximum reference height;
depositing a layer of resist above said isolation layer;
removing the resist in order to retain the resist only above the void space between the structuring material patterns and leave the isolation layer apparent above the structuring material patterns;
removing material of the isolation layer from the apparent zone of the isolation layer;
removing the remaining resist in order to retain walls made of said material of the isolation layer between the structuring material patterns.

8. The method according to claim 6, further comprising, after the conformally depositing of the first reflective layer and before depositing the layer made of the dielectric material intended to form the dielectric patterns of the Fabry-Perot cavities, the following steps of:
depositing a layer of resist covering all the structuring material patterns by having an upper surface, each point of which is located at a height relative to the carrier substrate greater than the maximum reference height;
removing the resist between the structuring material patterns in order to retain the resist only above the structuring material patterns;
depositing an isolation layer, said isolation layer covering all the structuring material patterns covered by resist and filling the space between said patterns, by having an upper surface each point of which is located at a height relative to the carrier substrate greater than the maximum reference height;
removing the material of the isolation layer located above the structuring material patterns and the remaining resist in order to retain walls made of said material of the isolation layer between the structuring material patterns.

9. The method according to claim 7, wherein said material of the isolation layer is a sacrificial material, said method comprising:
depositing a layer of resist onto the second reflective layer;
removing the resist from the zones above the space between the structuring material patterns;
removing the material of the second reflective layer, the dielectric material intended to form the dielectric patterns of the Fabry-Perot cavities and the sacrificial material in the zones above the space between the structuring material patterns so as to form void walls between the structuring material patterns and between the overhanging Fabry-Perot cavities;
removing the remaining resist.

10. The method according to claim 7, wherein said material of the isolation layer is a low optical index dielectric material, comprising:
depositing a layer of resist onto the second reflective layer;
removing the resist from the zones above the space(s) between the structuring material patterns;
removing the material of the second reflective layer and the dielectric material from the zones not protected by the remaining resist so as to reach the low optical index dielectric material;
depositing a layer of the low optical index dielectric material above the remaining resist and supplementing the dielectric material already present between the structuring material patterns so as to fill the void between the overhanging Fabry-Perot cavities;
removing the resist and the low optical index dielectric material above the resist zones leaving the low optical index material between the structuring material patterns and between the overhanging Fabry-Perot cavities so as to form dielectric isolation walls.
